(19) United States
(12) Patent Application Publication
(10) Pub. No.: US 2022/0137186 A1
(43) Pub. Date: May 5, 2022

(54) LIGHT-EMITTING ELEMENT DRIVE DEVICE AND OPTICAL RANGE-FINDING DEVICE

(71) Applicant: DENSO CORPORATION, Kariya-city (JP)

(72) Inventors: Masato NAKAJIMA, Kariya-city (JP); Yoshiaki HOASHI, Kariya-city (JP)

(21) Appl. No.: 17/647,939

(22) Filed: Jan. 13, 2022

Related U.S. Application Data
(63) Continuation of application No. PCT/JP2020/027222, filed on Jul. 13, 2020.

(30) Foreign Application Priority Data
Jul. 18, 2019 (JP) 2019-132390
Jul. 8, 2020 (JP) 2020-117647

(51) Int. Cl. G01S 7/484; H01S 5/042; G01S 17/10

(52) U.S. Cl. CPC G01S 7/484; G01S 17/10; H01S 5/0428

(57) ABSTRACT

A light-emitting element drive device for driving a light-emitting element includes a capacitor that is charged by a power supply and is for supplying a current to the light-emitting element, a first wire for allowing the current to flow from the capacitor to the light-emitting element, a second wire through which a current that is output from the light-emitting element flows, a first switch for switching a state of the capacitor between a charged state in which the capacitor is charged by the power supply and a discharged state in which the current is supplied from the capacitor to the light-emitting element, a diode that is reversely connected to the first wire and the second wire in parallel with the light emitting element, and a resistance element connected in series with the diode. The diode is a body diode included in a field-effect transistor.

### CROSS-REFERENCE TO RELATED APPLICATION

This application is the U.S. bypass application of International Application No. PCT/JP2020/027222 filed on Jul. 13, 2020, which designated the U.S. and claims priority to Japanese Patent Application No. 2019-132390, filed on Jul. 18, 2019, and Japanese Patent Application No. 2020-117647, filed on Jul. 8, 2020, the contents of all of which are incorporated herein by reference.

### TECHNICAL FIELD

The present disclosure relates to a light-emitting element drive device and an optical range-finding device.

### BACKGROUND

Known drive devices cause a light-emitting element to emit light by an electric charge charged in a capacitor from a power supply in order to cause the light-emitting element to emit light in short pulses (for example, refer to JP 2017-28235 A).

### SUMMARY

A first aspect of the present disclosure provides a light-emitting element drive device for driving a light-emitting element. The light-emitting element drive device includes a capacitor, a first wire, a second wire, a first switch, a diode, and a resistance element. The capacitor is charged by a power supply and is for supplying a current to the light-emitting element. The first wire is for allowing the current to flow from the capacitor to the light-emitting element. A current that is output from the light-emitting element flows through the second wire. The first switch is for switching a state of the capacitor between a charged state in which the capacitor is charged by the power supply and a discharged state in which the current is supplied from the capacitor to the light-emitting element. The diode is reversely connected to the first wire and the second wire in parallel with the light emitting element. The resistance element is connected in series with the diode, and the diode is a body diode included in a field-effect transistor.

A second aspect of the present disclosure provides a light-emitting element drive device for driving a light-emitting element. The light-emitting element drive device includes a capacitor, a first wire, a second wire, a first switch, a diode, and a resistance element. The capacitor is charged by a power supply and is for supplying a current to the light-emitting element. The first wire is for allowing the current to flow from the capacitor to the light-emitting element. A current that is output from the light-emitting element flows through the second wire. The first switch is for switching a state of the capacitor between a charged state in which the capacitor is charged by the power supply and a discharged state in which the current is supplied from the capacitor to the light-emitting element. The diode is reversely connected to the first wire and the second wire in parallel with the light emitting element. The resistance element is connected in series with the diode, and the first switch is located on the first wire.

A third aspect of the present disclosure provides an optical range-finding device. The optical range-finding device is a light-emitting element drive device for driving a light-emitting element, and includes a capacitor, a first wire, a second wire, a first switch, a diode, a second switch, a light-receiving element, an intensity signal output section, and a measuring unit. The capacitor is charged by a power supply and is for supplying a current to the light-emitting element. The first wire is for allowing the current to flow from the capacitor to the light-emitting element. A current that is output from the light-emitting element flows through the second wire. The first switch is for switching a state of the capacitor between a charged state in which the capacitor is charged by the power supply and a discharged state in which the current is supplied from the capacitor to the light-emitting element. The diode is reversely connected to the first wire and the second wire in parallel with the light emitting element. The second switch is connected between terminals of the capacitor and is for causing the capacitor to be discharged. The light-receiving element receives reflected light from an object to which light is projected by the light-emitting element. The intensity signal output section outputs an intensity signal representing an intensity of the reflected light received by the light-receiving element. The measuring unit detects a peak signal from the intensity signal sequentially output from the intensity signal output section and measures a distance to the object in accordance with a time taken from when light is emitted from the light-emitting element to when the peak signal is detected.

### BRIEF DESCRIPTION OF THE DRAWINGS

The above features of the present disclosure will be made clearer by the following detailed description, given referring to the appended drawings. In the accompanying drawings:

FIG. 1 is a diagram illustrating a schematic configuration of an optical range-finding device;

FIG. 2 is a diagram illustrating a configuration of the optical range-finding device in more detail;

FIG. 3 is a diagram illustrating a configuration of a light-receiving surface;

FIG. 4 is a graph showing an example of a histogram;

FIG. 5 is a diagram of a light-emitting element drive device according to a first embodiment;

FIG. 6 is a timing chart according to the first embodiment;

FIG. 7 is a graph showing an experimental result of light output;

FIG. 8 is a diagram of a light-emitting element drive device according to a second embodiment;

FIG. 9 is a flowchart according to the second embodiment; and

FIG. 10 is a timing chart according to the second embodiment.

### DETAILED DESCRIPTION OF THE PREFERRED EMBODIMENTS

A light-emitting element used in an optical range-finding device such as a Light Detection and Ranging (LiDAR) device is required to allow a large amount of current to flow in a short time to enhance the accuracy in measuring the distance to an object. Allowing a large amount of current to flow from the capacitor to the light-emitting element in a short time may cause a surge voltage to be applied to the light-emitting element after the light emission due to the influence of parasitic inductance of a wire and may possibly deteriorate the light-emitting element. Thus, a diode may be reversely connected in parallel with the light-emitting element. Unfortunately, the inventors of the present application found that a resonant circuit formed by the reverse connection of the diode may possibly cause a secondary emission of the light-emitting element. Such an issue has never arisen in emitting light with a pulse width of about some tens of nanoseconds and is a new issue that emerges by driving the light-emitting element under light-emitting conditions completely different from before such as allowing a large amount of current of about 100 A to flow with a pulse width of several nanoseconds.

The present disclosure is achieved in the following aspects.

A first aspect of the present disclosure provides a light-emitting element drive device for driving a light-emitting element. The light-emitting element drive device includes a capacitor, a first wire, a second wire, a first switch, a diode, and a resistance element. The capacitor is charged by a power supply and is for supplying a current to the light-emitting element. The first wire is for allowing the current to flow from the capacitor to the light-emitting element. A current that is output from the light-emitting element flows through the second wire. The first switch is for switching a state of the capacitor between a charged state in which the capacitor is charged by the power supply and a discharged state in which the current is supplied from the capacitor to the light-emitting element. The diode is reversely connected to the first wire and the second wire in parallel with the light emitting element. The resistance element is connected in series with the diode, and the diode is a body diode included in a field-effect transistor.

A second aspect of the present disclosure provides a light-emitting element drive device for driving a light-emitting element. The light-emitting element drive device includes a capacitor, a first wire, a second wire, a first switch, a diode, and a resistance element. The capacitor is charged by a power supply and is for supplying a current to the light-emitting element. The first wire is for allowing the current to flow from the capacitor to the light-emitting element. A current that is output from the light-emitting element flows through the second wire. The first switch is for switching a state of the capacitor between a charged state in which the capacitor is charged by the power supply and a discharged state in which the current is supplied from the capacitor to the light-emitting element. The diode is reversely connected to the first wire and the second wire in parallel with the light emitting element. The resistance element is connected in series with the diode, and the first switch is located on the first wire.

According to the light-emitting element drive device of the aspects, since the diode is connected in parallel to the light-emitting element, even if a surge voltage occurs due to parasitic inductance of the second wire, a current is prevented from flowing in reverse to the light-emitting element. This inhibits the deterioration of the light-emitting element due to the occurrence of the surge voltage. Furthermore, since a resistance element is connected in series with the diode, the capacitor is prevented from being recharged by the surge voltage. As a result, the secondary emission of the light-emitting element is prevented from occurring due to the occurrence of the surge voltage.

A third aspect of the present disclosure provides an optical range-finding device. The optical range-finding device is a light-emitting element drive device for driving a light-emitting element, and includes a capacitor, a first wire, a second wire, a first switch, a diode, a second switch, a light-receiving element, an intensity signal output section, and a measuring unit. The capacitor is charged by a power supply and is for supplying a current to the light-emitting element. The first wire is for allowing the current to flow from the capacitor to the light-emitting element. A current that is output from the light-emitting element flows through the second wire. The first switch is for switching a state of the capacitor between a charged state in which the capacitor is charged by the power supply and a discharged state in which the current is supplied from the capacitor to the light-emitting element. The diode is reversely connected to the first wire and the second wire in parallel with the light emitting element. The second switch is connected between terminals of the capacitor and is for causing the capacitor to be discharged. The light-receiving element receives reflected light from an object to which light is projected by the light-emitting element. The intensity signal output section outputs an intensity signal representing an intensity of the reflected light received by the light-receiving element. The measuring unit detects a peak signal from the intensity signal sequentially output from the intensity signal output section and measures a distance to the object in accordance with a time taken from when light is emitted from the light-emitting element to when the peak signal is detected.

According to the optical range-finding device of the aspect, since the diode is connected in parallel to the light-emitting element, even if a surge voltage occurs due to parasitic inductance of the second wire, a current is prevented from flowing in reverse to the light-emitting element. This inhibits the deterioration of the light-emitting element due to the occurrence of the surge voltage. Since the second switch for causing the capacitor to be discharged is located between the terminals of the capacitor, even if the capacitor is recharged by the occurrence of the surge voltage, the capacitor is discharged by switching on the second switch. As a result, the secondary emission of the light-emitting element is prevented from occurring due to the occurrence of the surge voltage.

The present disclosure can also be achieved in various forms other than the light-emitting element drive device. For example, the present disclosure may be achieved in the form of a method for driving the light-emitting element, an optical range-finding device including the light-emitting element drive device, or the like.

### A. First Embodiment

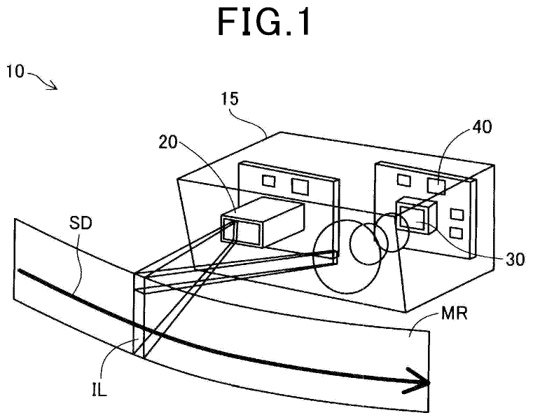

As shown in FIG. 1, an optical range-finding device 10 according to one embodiment of the present disclosure includes a housing 15, a light emitter 20, a light receiver 30, and a measuring unit 40. The light emitter 20 emits illumination light IL over a predetermined measurement range MR in space. In the present embodiment, the light emitter 20 scans the illumination light IL in a scanning direction SD. The illumination light IL is rectangular, and the longitudinal direction of the illumination light IL is orthogonal to the scanning direction SD. The light receiver 30 receives reflected light from the range including the measurement range MR on which the illumination light IL is projected. The measuring unit 40 measures the distance to an object that exists in the measurement range MR in accordance with the intensity of the reflected light received by the light receiver 30. The optical range-finding device 10 is mounted on, for example, a vehicle and is used for detecting an obstacle and measuring the distance to the obstacle.

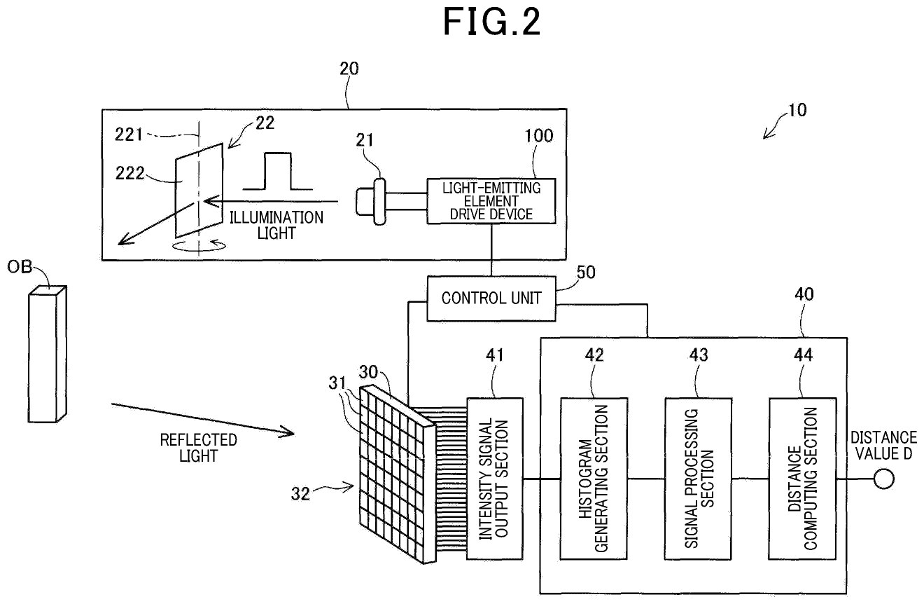

FIG. 2 shows a more specific configuration of the optical range-finding device 10. As shown in FIG. 2, the optical range-finding device 10 includes a control unit 50 in addition to the light emitter 20, the light receiver 30, and the measuring unit 40, which are shown in FIG. 1. The control unit 50 is configured as a computer including a CPU and a memory and controls the light emitter 20, the light receiver 30, and the measuring unit 40.

The light emitter 20 includes a light-emitting element 21 and a light-emitting element drive device 100. The light-emitting element 21 of the present embodiment is a semiconductor laser diode. The light-emitting element 21 is driven by the light-emitting element drive device 100 and emits a pulsed laser beam as the illumination light. The specific configuration of the light-emitting element drive device 100 will be described later. The illumination light emitted from the light-emitting element 21 is formed into the illumination light IL that is vertically long as shown in FIG. 1 using a non-illustrated optical system. The light emitter 20 includes a scanner 22. The scanner 22 rotates a mirror 222 about a rotary shaft 221 to perform a one-dimensional scanning of the illumination light IL over the measurement range MR. The mirror 222 is constituted by, for example, a Micro-Electro-Mechanical Systems (MEMS) mirror. The rotation of the mirror 222 is controlled by the control unit 50.

The illumination light emitted by the light emitter 20 is reflected by an object OB in the measurement range MR. The reflected light reflected by the object OB is received by the light receiver 30.

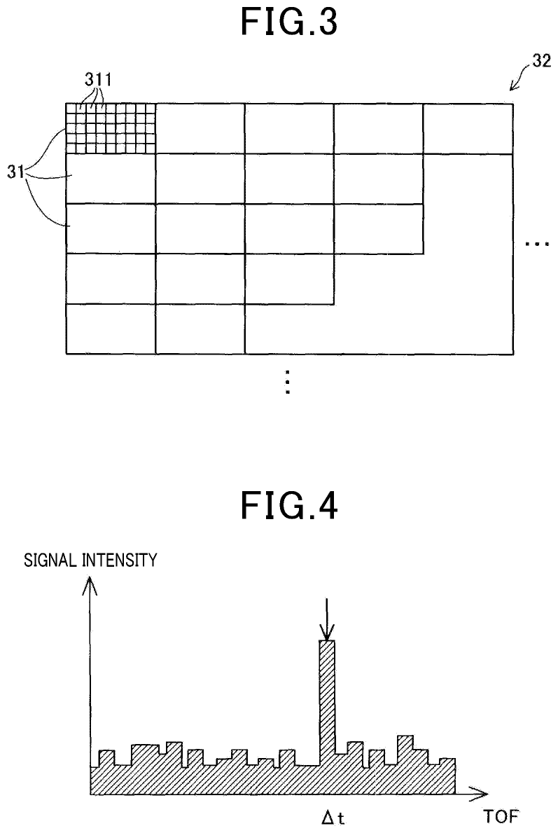

As shown in FIGS. 2 and 3, the light receiver 30 includes two-dimensionally arranged pixels 31 on a light-receiving surface 32, which receives the reflected light from objects. As shown in FIG. 3, each pixel 31 includes multiple light-receiving elements 311, which receive the reflected light from the object OB. In the present embodiment, each pixel 31 includes a total of 45 light-receiving elements 311 (9 pixels across and 5 pixels down). Each pixel 31 outputs 0 to 45 pulse signals in accordance with the intensity of the received light. The light-receiving surface 32 of the light receiver 30 is constituted by the pixels 31, which are arranged so that there are, for example, 64 pixels down and 256 pixels across.

An intensity signal output section 41 is connected to the light receiver 30. The intensity signal output section 41 is a circuit that outputs an intensity signal representing the intensity of the reflected light detected by the light-receiving elements 311. The intensity signal output section 41 adds up the number of pulse signals output at substantially the same time from the light-receiving elements 311 included in the pixels 31 per pixel. The addition value is output as an intensity signal representing the intensity of the reflected light received by each pixel 31. In the present embodiment, since each pixel includes 45 light-receiving elements 311 as described above, the intensity signal output section 41 outputs an intensity signal having a value of 0 to 45 per pixel 31.

The measuring unit 40 detects a peak signal from the intensity signals sequentially output from the intensity signal output section 41 and functions to measure the distance to the object OB based on the time taken from the emission of light from the light emitter 20 to when the peak signal is detected. The measuring unit 40 includes a histogram generating section 42, a signal processing section 43, and a distance computing section 44 to perform this function. These sections are configured as one integrated circuit or two or more integrated circuits. Note that, these sections may be functional units achieved by software with a CPU executing programs.

The histogram generating section 42 is a circuit that generates a histogram per pixel 31 based on the intensity signal output from the intensity signal output section 41. FIG. 4 shows an example of a histogram. The class of the histogram indicated on the horizontal axis represents the time of flight of light from when the illumination light IL is emitted from the light emitter 20 to when the reflected light is received by the pixel 31. Hereinafter, the time is referred to as Time of Flight (TOF). The frequency of the histogram indicated on the vertical axis is the value of the intensity signal output from the intensity signal output section 41 and represents the intensity of the light reflected from an object. The histogram generating section 42 generates a histogram by recording the intensity signal output from the intensity signal output section 41 per TOF. When the object OB exists in the measurement range MR, the light is reflected from the object OB, and the intensity signal is recorded in the class of the TOF corresponding to the distance to the object OB. The signal processing section 43 is a circuit that detects the portion of the class where the frequency is the maximum in the histogram as the peak signal. The peak signal in the histogram indicates that the object exists at a position (distance) determined by the TOF corresponding to the peak signal. The signals other than the peak signal are signals caused by the influence of, for example, ambient light. The signal processing section 43 may detect the portion of the class where the frequency is greater than a predetermined threshold value as the peak value.

The distance computing section 44 is a circuit that obtains a distance value D from the TOF corresponding to the peak signal detected by the signal processing section 43. The distance computing section 44 calculates the distance value D using the following formula (1) where the TOF corresponding to the peak signal is “Δt”, the speed of light is “c”, and the distance value is “D”. The distance computing section 44 calculates the distance value D of the entire histogram, that is, all the pixels 31.

$$D = ( c \times Δ t ) / 2 \qquad ( 1 )$$

The distance value D of each pixel 31 measured by the measuring unit 40 is output from the optical range-finding device 10 to, for example, an ECU of the vehicle. The ECU of the vehicle can detect an obstacle in the measurement range MR and measure the distance to the obstacle using the distance value of each pixel 31 acquired from the optical range-finding device 10.

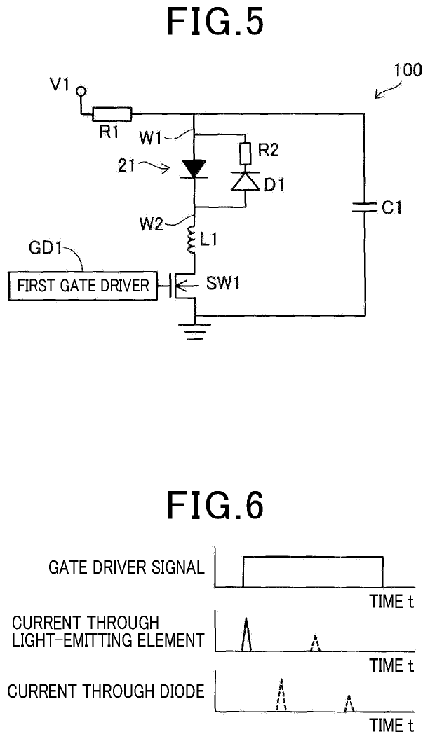

As shown in FIG. 5, the light-emitting element drive device 100, which drives the light-emitting element 21, includes a capacitor C1, a first switch SW1, and a diode D1.

The capacitor C1 is connected to a power supply V1 through a first resistance element R1. The power supply V1 is a DC power supply with a constant voltage of 100 to 200 V. The first resistance element R1 has a resistance value of, for example, 10 k to 100 kΩ. The capacitor C1 is charged by the power supply V1 through the first resistance element R1. The time required for charging is determined in accordance with the capacity of the capacitor C1 and the resistance value of the first resistance element R1. The number of capacitors C1 is not limited to one, and multiple capacitors may be connected in parallel.

The capacitor C1 supplies a current to the light-emitting element 21. The capacitor C1 and the light-emitting element 21 are connected by a first wire W1. The first wire W1 allows a current to flow from the capacitor C1 to the light-emitting element 21. The first wire W1 is connected to the anode terminal of the light-emitting element 21. For example, a large current of approximately 100 A flows from the capacitor C1 to the light-emitting element 21 in several nanoseconds. The supply time period (pulse width) and a current value of a current from the capacitor C1 to the light-emitting element 21 are not limited to this. For example, the supply time period can be set to 2 to 10 nanoseconds, and a current value can be set to 50 to 250 A.

The light-emitting element 21 is connected to the ground through a second wire W2. The second wire W2 is connected to the cathode terminal of the light-emitting element 21. The current that is output from the light-emitting element 21 flows through the second wire W2. The second wire W2 has parasitic inductance L1 corresponding to the length of the wire. In the present embodiment, the first switch SW1 is located on the second wire W2. In the present embodiment, the first switch SW1 is constituted by a semiconductor switching element. The first switch SW1 is switched by a first gate driver GD1 in response to an instruction from the control unit 50.

The first switch SW1 switches charged/discharged states of the capacitor C1 between the charged state in which the capacitor C1 is charged by the power supply V1 and the discharged state in which a current is supplied from the capacitor C1 to the light-emitting element 21. In the present embodiment, upon switching off the first switch SW1, the power supply V1 is disconnected from the ground, so that the capacitor C1 is brought into the charged state. Upon switching on the first switch SW1, the capacitor C1 is connected to the ground through the light-emitting element 21, so that the capacitor C1 is brought into the discharged state. In the present description, switching on means electrically connecting the wire upstream of the switch to the wire downstream of the switch, and switching off means disconnecting the wire upstream of the switch from the wire downstream of the switch.

The diode D1 is connected in parallel to the light-emitting element 21 and reverse to the first wire W1 and the second wire W2. That is, the cathode terminal of the diode D1 is connected to the first wire W1, and the anode terminal of the diode D1 is connected to the second wire W2. More specifically, in the present embodiment, the cathode terminal of the diode D1 is connected to the first wire W1 through a second resistance element R2, which is connected in series with the cathode terminal of the diode D1. The anode terminal of the diode D1 is connected to the section of the second wire W2 between the light-emitting element 21 and the first switch SW1. The second resistance element R2 may be a resistor or a ferrite bead inductor.

Like the timing chart shown in FIG. 6, in response to switching on the first switch SW1 by the first gate driver GD1, the light-emitting element 21 is electrically connected to the ground, so that the electric charge charged in the capacitor C1 flows to the light-emitting element 21, causing the light-emitting element 21 to emit light. The time period during which the first switch SW1 is switched on by the first gate driver GD1 is, for example, 30 to 60 nanoseconds. The time period during which the light-emitting element 21 emits light is, for example, 3 to 6 nanoseconds.

After the emission of light by the light-emitting element 21, a surge voltage may possibly occur in the second wire W2 due to the influence of the parasitic inductance L1 that exists in the second wire W2. The greater the current, the greater the surge voltage becomes, and the shorter the pulse width, the greater the surge voltage becomes. In the present embodiment, since the diode D1 is reverse-connected in parallel to the light-emitting element 21, even if a surge voltage occurs, the current caused by the surge voltage flows through the diode D1 and does not flow to the light-emitting element 21. When the current flows to the diode D1, the capacitor C1 is charged by that current. When the voltage across the capacitor C1 exceeds the forward voltage of the light-emitting element 21, a current flows again from the capacitor C1 to the light-emitting element 21, which may undesirably cause the light-emitting element 21 to emit light at an unintentional point in time as shown by a broken line in FIG. 6. Such a light emission is also referred to as a secondary emission, and such a phenomenon is also called a resonance phenomenon. However, in the present embodiment, since the second resistance element R2 is connected in series with the diode D1, the current that flowed through the diode D1 is attenuated by flowing through the second resistance element R2. This inhibits the resonance phenomenon as described above and thus inhibits the occurrence of the secondary emission.

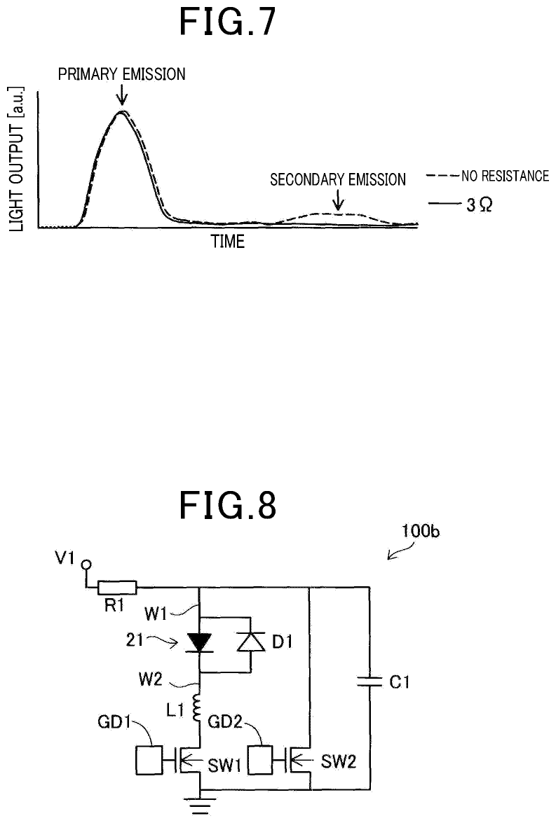

The second resistance element R2 with an excessively large resistance value hinders a current from flowing to the diode D1 and the second resistance element R2 when a surge voltage occurs, which increases the possibility that a current flows in reverse to the light-emitting element 21. Thus, the resistance value of the second resistance element R2 is preferably, for example, 3 to 6Ω. FIG. 7 shows the experimental result of the light output when a resistance element with a resistance of 3Ω is provided as the second resistance element R2. The horizontal axis in FIG. 7 indicates the time elapsed from when the first switch SW1 is switched on, and the vertical axis indicates the level of the light output of the light-emitting element 21. As shown in FIG. 7, the light-emitting element drive device 100 provided with the second resistance element R2 inhibits the occurrence of the secondary emission after the primary emission of the light-emitting element 21.

As described above, according to the light-emitting element drive device 100 of the first embodiment, the diode D1 is reverse-connected in parallel to the light-emitting element 21. Thus, when a surge voltage is caused by the parasitic inductance L1, the light-emitting element 21 is protected from the surge voltage. Furthermore, connecting the second resistance element R2 in series with the diode D1 inhibits the light-emitting element 21 from causing the secondary emission in response to the occurrence of the surge voltage.

Note that, although the second resistance element R2 is connected in series with the cathode terminal of the diode D1 in the present embodiment, the second resistance element R2 may be connected in series with the anode terminal of the diode D1.

Furthermore, although the first switch SW1 is located on the second wire W2 in the present embodiment, the first switch SW1 may be located on the first wire W1. Specifically, the first switch SW1 may be located on part of the first wire W1 upstream of the joint portion with the diode D1.

Additionally, although the first resistance element R1 is located downstream of the power supply V1 in the present embodiment, other elements or a circuit may be provided instead of the first resistance element R1. For example, instead of the first resistance element R1, a coil may be provided, or a diode and a coil may be provided in series. Alternatively, a switch that is switched off during discharging of the capacitor C1 may be provided.

### B. Second Embodiment

As shown in FIG. 8, a light-emitting element drive device 100b according to a second embodiment includes a second switch SW2. The second switch SW2 is connected between the terminals of the capacitor C1, that is, between the first wire W1 and the ground. Other structures of the light-emitting element drive device 100b are the same as the light-emitting element drive device 100 of the first embodiment shown in FIG. 5. In the present embodiment, the second switch SW2 is constituted by a semiconductor switching element. The second switch SW2 is switched by a second gate driver GD2 in response to the instruction from the control unit 50.

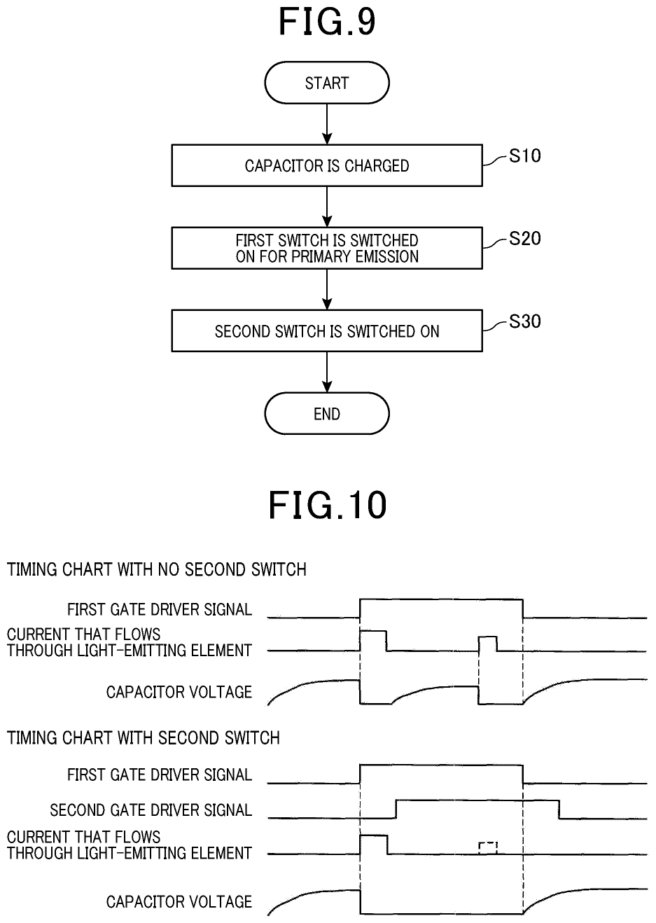

As shown in FIG. 9, first, at step S10, the capacitor C1 is charged by the power supply V1. Subsequently, at step S20, the first switch SW1 is switched on, so that the primary emission of the light-emitting element 21 takes place. Then, as described above, the capacitor C1 is sometimes recharged due to the occurrence of a surge voltage caused by the parasitic inductance L1. In the present embodiment, after the primary emission, at step S30, the second switch SW2 is switched on to cause the capacitor C1 that has been recharged to be discharged before the secondary emission occurs. As shown in FIG. 10, while the secondary emission may occur without the second switch SW2, the occurrence of the secondary emission can be inhibited by providing the second switch SW 2 and switching on the second switch SW 2 after the primary emission to cause the capacitor C1 to be discharged.

FIG. 10 shows an example in which the first switch SW1 and the second switch SW2 are switched on for the same length of time period. However, the time periods do not necessarily have to be the same. For example, the second switch SW2 only needs to be set so that the second switch

SW2 is switched on immediately after the termination of the primary emission, and the switch-on time covers the time period during which the secondary emission occurs. Furthermore, the first switch SW1 may be switched off at any point in time as long as the first switch SW1 is kept on until the primary emission is terminated. Note that, the first switch SW1 is preferably switched off before the secondary emission occurs.

According to the structure of the light-emitting element drive device 100b of the present embodiment shown in FIG. 8, the second resistance element R2 is not connected to the diode D1 However, in the present embodiment also, the second resistance element R2 may be connected in series with the diode D1 like in the first embodiment. This more reliably inhibits the occurrence of the secondary emission.

### C. Other Embodiments

(C-1) The diode D1 shown in FIGS. 5 and 8 may be a body diode included in, for example, Metal-Oxide-Semiconductor Field-Effect Transistor (MOSFET). The FET may be an N-channel FET or a P-channel FET.

(C-2) The device including the light-emitting element drive device 100 does not necessarily have to be the optical range-finding device 10. For example, the light-emitting element drive device 100 may be provided in an image display including the light-emitting element 21. Furthermore, the light-emitting element 21 is not limited to a semiconductor laser diode and may be other elements such as a light-emitting diode in accordance with the use of a device including the light-emitting element drive device 100.

(C-3) In the above-described embodiment, the optical range-finding device 10 uses an optical system in which the optical axis in light emission and the optical axis in light reception differ from each other. In contrast, the optical range-finding device 10 may use an optical system in which the optical axis in light emission and the optical axis in light reception match with each other. In the above-described embodiments, the pixels are arranged in a planar form in the vertical direction and the horizontal direction, but the pixels 31 may be arranged in a line in a predetermined direction. Furthermore, in the above-described embodiments, the optical range-finding device 10 uses, as a scanning system, a 1D scanning system that scans rectangular light in one direction but may use a 2D scanning system that scans point light in two-dimensional directions. Also, the optical range-finding device 10 may be a device that does not scan light but emits a flash of light over a wide range.

(C-4) In the above-described embodiments, the pixels 31 included in the light receiver 30 can be constituted by light-receiving elements such as PIN photodiodes, avalanche photodiodes, and single-photon avalanche diodes (SPADs). In this case, with the light-receiving elements capable of outputting a stepless or multistep level signal corresponding to the intensity of the reflected light that has been received, the distance can be measured using the level of the signal without generating a histogram.

The present disclosure is not limited to the above embodiments and can be achieved by various configurations without departing from the spirit of the present disclosure. For example, the technical characteristics of each embodiment may be replaced or combined as required to solve some or all of the above-described problems or achieve some or all of the above-described advantages. Unless otherwise the technical characteristics are described as essential in the present description, the technical characteristics may be omitted as required.

What is claimed is:

1. A light-emitting element drive device for driving a light-emitting element, the light-emitting element drive device comprising:
a capacitor that is charged by a power supply and is for supplying a current to the light-emitting element;
a first wire for allowing the current to flow from the capacitor to the light-emitting element;
a second wire through which a current that is output from the light-emitting element flows;
a first switch for switching a state of the capacitor between a charged state in which the capacitor is charged by the power supply and a discharged state in which the current is supplied from the capacitor to the light-emitting element;
a diode that is reversely connected to the first wire and the second wire in parallel with the light emitting element; and
a resistance element connected in series with the diode, wherein
the diode is a body diode included in a field-effect transistor.

2. A light-emitting element drive device for driving a light-emitting element, the light-emitting element drive device comprising:
a capacitor that is charged by a power supply and is for supplying a current to the light-emitting element;
a first wire for allowing the current to flow from the capacitor to the light-emitting element;
a second wire through which a current that is output from the light-emitting element flows;
a first switch for switching a state of the capacitor between a charged state in which the capacitor is charged by the power supply and a discharged state in which the current is supplied from the capacitor to the light-emitting element;
a diode that is reversely connected to the first wire and the second wire in parallel with the light emitting element; and
a resistance element connected in series with the diode, wherein
the first switch is located on the first wire.

3. The light-emitting element drive device according to claim 2, wherein
the diode is a body diode included in a field-effect transistor.

4. An optical range-finding device comprising:
a light-emitting element drive device for driving a light-emitting element, the light-emitting element drive device comprising:
a capacitor that is charged by a power supply and is for supplying a current to the light-emitting element;
a first wire for allowing the current to flow from the capacitor to the light-emitting element;
a second wire through which a current that is output from the light-emitting element flows;
a first switch for switching a state of the capacitor between a charged state in which the capacitor is charged by the power supply and a discharged state in which the current is supplied from the capacitor to the light-emitting element;
a diode that is reversely connected to the first wire and the second wire in parallel with the light emitting element; and
a resistance element connected in series with the diode, wherein
the diode is a body diode included in a field-effect transistor,
a light-receiving element that receives reflected light from an object to which light is projected by the light-emitting element;
an intensity signal output section that outputs an intensity signal representing an intensity of the reflected light received by the light-receiving element; and
a measuring unit that detects a peak signal from the intensity signal sequentially output from the intensity signal output section and measures a distance to the object in accordance with a time taken from when light is emitted from the light-emitting element to when the peak signal is detected.

5. An optical range-finding device comprising:
a light-emitting element drive device for driving a light-emitting element, the light-emitting element drive device comprising:
a capacitor that is charged by a power supply and is for supplying a current to the light-emitting element;
a first wire for allowing the current to flow from the capacitor to the light-emitting element;
a second wire through which a current that is output from the light-emitting element flows;
a first switch for switching a state of the capacitor between a charged state in which the capacitor is charged by the power supply and a discharged state in which the current is supplied from the capacitor to the light-emitting element;
a diode that is reversely connected to the first wire and the second wire in parallel with the light emitting element; and
a second switch that is connected between terminals of the capacitor and is for causing the capacitor to be discharged;
a light-receiving element that receives reflected light from an object to which light is projected by the light-emitting element;
an intensity signal output section that outputs an intensity signal representing an intensity of the reflected light received by the light-receiving element; and
a measuring unit that detects a peak signal from the intensity signal sequentially output from the intensity signal output section and measures a distance to the object in accordance with a time taken from when light is emitted from the light-emitting element to when the peak signal is detected.

6. The optical range-finding device according to claim 5, wherein
the second switch is switched on after the capacitor is brought into the discharged state by the first switch, which causes the current to flow from the capacitor to the light-emitting element.
